(19) United States
(12) Patent Application Publication
(10) Pub. No.: US 2002/0192966 A1
(43) Pub. Date: Dec. 19, 2002

(54) In situ sensor based control of semiconductor processing procedure

(76) Inventors: Arulkumar P. Shanmugasundram, Sunnyvale, CA (US); Alexander T. Schwarm, Austin, TX (US)

Correspondence Address: APPLIED MATERIALS, INC., 2881 SCOTT BLVD. M/S 2061, SANTA CLARA, CA, 95050, US

(21) Appl. No.: 09/943,383

(22) Filed: Aug. 31, 2001

Related U.S. Application Data
(60) Provisional application No. 60/298,878, filed on Jun. 19, 2001.
(60) Provisional application No. 60/305,141, filed on Jul. 16, 2001.

(51) Int. Cl. C23F 1/00; H01L 21/461; H01L 21/66

(52) U.S. Cl. 438/692; 438/14; 156/345.12; 156/345.13

(57) ABSTRACT

A wafer property is controlled by a semiconductor processing tool using data collected from an in situ sensor. Initially, data relating to the wafer property is collected by the in situ sensor during a process executed according to wafer recipe parameters. Subsequently, the process may be adjusted by modifying the recipe parameters according to comparisons between the data collected by the in situ sensor relating to the wafer property and the results predicted by a process model used to predict wafer outputs. A subsequent process utilizing the data collected by the in situ sensor is then executed. In at least some embodiments of the present invention the data may be used for run-to-run control on subsequent wafers processed by the tool.

### CROSS REFERENCE TO RELATED APPLICATION

This application claims the benefit of U.S. Provisional Applications Nos. 60/298,878 and 60/305,141, filed respectively on Jun. 19, 2001 and Jul. 16, 2001, both of which are incorporated herein by reference.

### FIELD OF THE INVENTION

The present invention relates generally to semiconductor manufacture. More particularly, the present invention relates to techniques for controlling semiconductor processing by using an in situ sensor to control a recipe parameter during a manufacturing process.

### BACKGROUND OF THE INVENTION

In the fabrication of integrated circuits, numerous integrated circuits are typically constructed simultaneously on a single semiconductor wafer. The wafer is then later subjected to a singulation process in which individual integrated circuits are singulated (i.e., extracted) from the wafer.

At certain stages of fabrication, it is often necessary to polish a surface of the semiconductor wafer. In general, a semiconductor wafer can be polished to remove high topography, surface defects such as crystal lattice damage, scratches, roughness, or embedded particles of dirt or dust. This polishing process is often referred to as mechanical planarization (MP) and is utilized to improve the quality and reliability of semiconductor stations. This process is usually performed during the formation of various devices and integrated circuits on the wafer.

The polishing process may also involve the introduction of a chemical slurry to facilitate higher removal rates and selectivity between films of the semiconductor surface. This polishing process is often referred to as chemical mechanical planarization (CMP).

One problem encountered in polishing processes is the non-uniform removal of the semiconductor surface. Removal rate is directly proportional to downward pressure on the wafer, rotational speeds of the platen and wafer, slurry particle density and size, slurry composition, and the effective area of contact between the polishing pad and the wafer surface. Removal caused by the polishing platen is also related to the radial position on the platen. Similarly, removal rates may vary across the wafer for a variety of other reasons including boundary effects, idling, consumable sets, etc.

Another problem in conventional polishing processes is the difficulty in removing non-uniform films or layers, which have been applied to the semiconductor wafer. During the fabrication of integrated circuits, a particular layer or film may have been deposited or grown in an uneven manner resulting in a non-uniform surface which is subsequently subjected to polishing processes. The thicknesses of such layers or films can be very small (on the order of 0.5 to 5.0 microns), thereby allowing little tolerance for non-uniform removal. A similar problem arises when attempting to polish warped surfaces on the semiconductor wafer. Warpage can occur as wafers are subjected to various thermal cycles during the fabrication of integrated circuits. As a result of the warpage, the semiconductor surface has high and low areas, whereby the high areas will be polished to a greater extent than the low areas.

As a result of these polishing problems, individual regions of the same semiconductor wafer can experience different polishing rates. As an example, one region may be polished at a much higher rate than the other regions, causing removal of too much material in the high rate region or removal of too little material in the lower rate regions.

A compounding problem associated with polishing semiconductor wafers is the difficulty in monitoring polishing conditions in an effort to detect and correct the above inherent polishing problems as they occur. It is common to conduct numerous pre-polishing measurements of the wafer before commencement of the polishing process, and then conduct numerous similar post-polishing measurements to determine whether the polishing process yielded the desired topography, thickness, and uniformity. However, these pre- and post-polishing measurements are labor intensive and result in a low product throughput.

Conventional techniques are known for controlling a polishing process in real time. In those techniques, polishing data is collected in real time by an in situ sensor. The data is used to adjust the pressure applied by an applicator during the wafer polishing process. However, these techniques do not utilize the data to modify the amount of time a wafer is polished to control the within wafer uniformity on the wafer. Similarly, they do not contemplate integrating the data collected by the in situ sensor with other information. Furthermore, data obtained using these techniques is utilized in a single polishing process and in particular, is used only as an indication of when the polishing process should stop, but not for use in fine-tuning the polishing process or for use in the polishing of subsequent wafers. As a result, the level of control provided is still not optimal. Accordingly, increasingly efficient techniques for processing such wafers are needed.

### SUMMARY OF THE INVENTION

The present invention addresses the problems described above by controlling a wafer property in a semiconductor processing tool using data collected from an in situ sensor (i.e., a sensor that is capable of collecting data during processing). In at least some embodiments of the present invention, data relating to the wafer property is collected during a process executed according to wafer recipe parameters. From there, the process is adjusted by modifying the recipe parameters according to comparisons between the data collected by the in situ sensor relating to the wafer property and the results predicted by a process model used to predict wafer outputs. A subsequent process to be performed by the tool by utilizing the data collected by the in situ sensor is then executed.

In at least some embodiments of the present invention, the wafer property to be controlled includes wafer thickness. In these instances, the tool may include multiple polishing stations, with each device being capable of controlling a polishing parameter, such as polishing time. Furthermore, data from each of the in situ sensors may be forwarded to a control system during execution of the process for greater control and accuracy.

Also, in at least some embodiments of the present invention, input data used by the wafer model may be collected from any of in situ, inline, or upstream tool sensors. Thus, the combination of data collected from the sensors may be integrated before being used by the model to generate recipe parameters. Furthermore, data collected from the inline or upstream tool sensors may be utilized to calibrate the in situ sensor.

### BRIEF DESCRIPTION OF THE DRAWINGS

Various objects, features, and advantages of the present invention can be more fully appreciated as the same become better understood with reference to the following detailed description of the present invention when considered in connection with the accompanying drawings, in which:

FIG. 1 is a perspective view of at least one example of a chemical mechanical planarization (CMP) apparatus;

FIG. 2 depicts a block diagram of a control system that can be used in conjunction with the CMP apparatus of FIG. 1;

FIG. 3 illustrates at least some examples of a number of parameter profiles implementable by the CMP apparatus 20 of FIG. 1 to produce a particular wafer property;

FIG. 4 depicts at least one example of a process implementable for controlling a manufacturing process of the present invention;

FIG. 5 depicts at least one example of a modeling process utilizable for optimizing recipe parameters according to the concepts of the present invention;

FIG. 6 depicts at least one example of a process implementable for controlling a manufacturing process of the present invention;

FIG. 7 is a high-level block diagram depicting aspects of computing devices contemplated as part of, and for use with at least some, embodiments of the present invention; and

FIG. 8 illustrates one example of a memory medium which may be used for storing a computer implemented process of at least some embodiments of the present invention.

### DETAILED DESCRIPTION OF THE INVENTION

In accordance with at least some embodiments of the present invention, a technique is provided for controlling a wafer property in a semiconductor processing tool using data collected from an in situ sensor. Specifically, at least some embodiments of the present invention contemplate utilizing data collected from an in situ sensor during a manufacturing or other similar process for optimizing subsequent processes. In this manner, the techniques of at least some embodiments of the present invention contemplate using this information in conjunction with the processing of subsequent wafers.

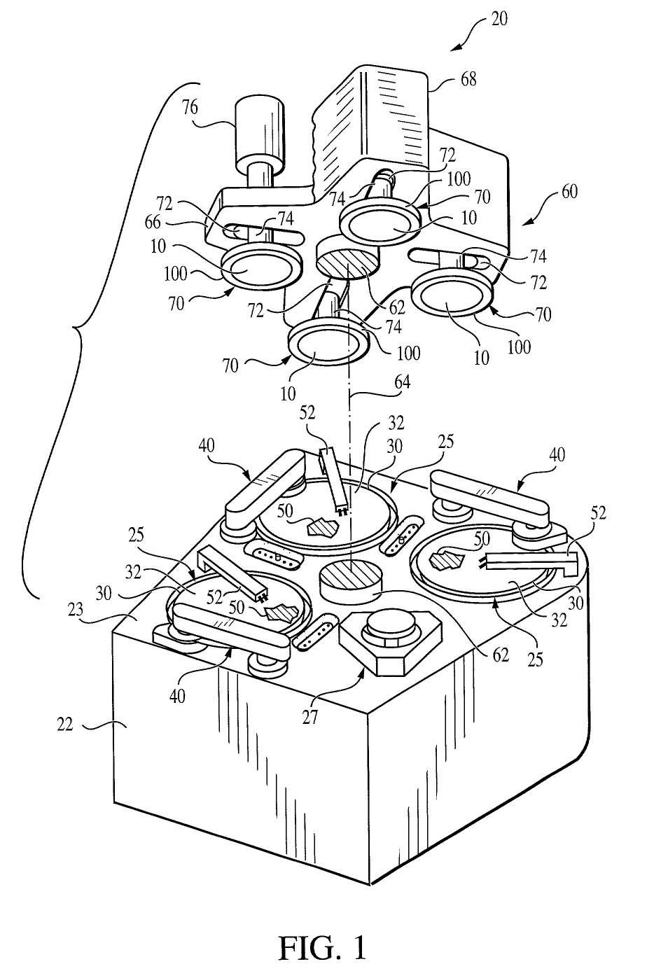

FIG. 1 depicts at least one example of a chemical mechanical planarization (CMP) apparatus 20 utilizable for implementing at least some aspects of the present invention.

Referring now to FIG. 1, the CMP apparatus 20 includes a lower machine base 22 with a table top 23 mounted thereon and a removable upper outer cover (not shown). Table top 23 supports a series of polishing stations 25, and a transfer station 27 for loading and unloading the substrates (e.g., wafers) 10. The transfer station may form a generally square arrangement with the three polishing stations.

Each polishing station includes a rotatable platen 30 on which is placed a polishing pad 32. If substrate 10 is an eight-inch (200 millimeter) or twelve-inch (300 millimeter) diameter disk, then platen 30 and polishing pad 32 will be about twenty or thirty inches in diameter, respectively. Platen 30 may be connected to a platen drive motor (not shown) located inside machine base 22. For most polishing processes, the platen drive motor rotates platen 30 at thirty to two-hundred revolutions per minute, although lower or higher rotational speeds may be used. Each polishing station 25 may further include an associated pad conditioner apparatus 40 to maintain the abrasive condition of the polishing pad.

A slurry 50 containing a reactive agent (e.g., deionized water for oxide polishing) and a chemically-reactive catalyzer (e.g., potassium hydroxide for oxide polishing) may be supplied to the surface of polishing pad 32 by a combined slurry/rinse arm 52. If polishing pad 32 is a standard pad, slurry 50 may also include abrasive particles (e.g., silicon dioxide for oxide polishing). Typically, sufficient slurry is provided to cover and wet the entire polishing pad 32. Slurry/rinse arm 52 includes several spray nozzles (not shown) which provide a high-pressure rinse of polishing pad 32 at the end of each polishing and conditioning cycle.

A rotatable multi-head carousel 60, including a carousel support plate 66 and a cover 68, is positioned above lower machine base 22. Carousel support plate 66 is supported by a center post 62 and rotated thereon about carousel axis 64 by a carousel motor assembly located within machine base 22. Multi-head carousel 60 includes four carrier head systems 70 mounted on carousel support plate 66 at equal angular intervals about axis 64. Three of the carrier head systems receive and hold substrates and polish them by pressing them against the polishing pads of polishing stations 25. One of the carrier head systems receives a substrate from and delivers the substrate to transfer station 27. The carousel motor may orbit the carrier head systems, and the substrates attached thereto, about carousel axis 64 between the polishing stations and the transfer station.

Each carrier head system includes a polishing or carrier head 100. Each carrier head 100 independently rotates about its own axis, and independently laterally oscillates in a radial slot 72 formed in carousel support plate 66. A carrier drive shaft 74 extends through slot 72 to connect a carrier head rotation motor 76 (shown by the removal of one-quarter of cover 68) to carrier head 100. There is one carrier drive shaft and motor for each head. Each motor and drive shaft may be supported on a slider (not shown) which can be linearly driven along the slot by a radial drive motor to laterally oscillate the carrier heads.

During actual polishing, three of the carrier heads are positioned at and above the three polishing stations. Each carrier head 100 lowers a substrate into contact with a polishing pad 32. Generally, carrier head 100 holds the substrate in position against the polishing pad and distributes a force across the back surface of the substrate. The carrier head also transfers torque from the drive shaft to the substrate. A description of a similar apparatus may be found in U.S. Pat. No. 6,159,079, the entire disclosure of which is incorporated herein by reference. A commercial embodiment of a CMP apparatus could be, for example, any of a number of processing stations or devices offered by Applied Materials, Inc. of Santa Clara, Calif. including, for example, any number of the Mirramesa™ and Reflexion™ line of CMP devices. Also, while the device depicted in FIG. 1 is implemented to perform polishing processes and includes any polishing stations, it is to be understood that the concepts of the present invention may be utilized in conjunction with various other types of semiconductor manufacturing processes and processing resources including for example non-CMP devices, etching tools, deposition tools, plating tools, etc. Other examples of processing resources include polishing stations, chambers, and/or plating cells, and the like.

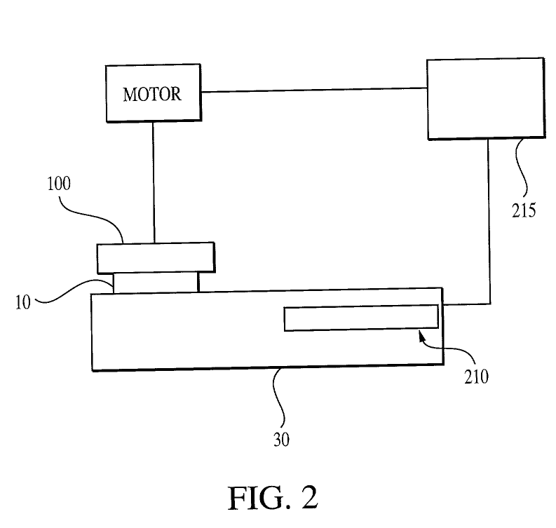

FIG. 2 depicts a block diagram of a control system that can be used to control CMP tool 20 (e.g., control the various polishing aspects of the tool). More specifically, an in situ sensor 210 may be utilized in real time to measure one or more wafer properties before, during, and after execution of a manufacturing process (though the measurements made during execution are of particular interest for at least some embodiments of the present invention). As one example, in situ sensor 210 may include a wafer thickness measuring device for measuring a topography of the wafer face during polishing. For instance, in situ sensor 210 may be implemented in the form of a laser interferometer measuring device, which employs interference of light waves for purposes of measurement. One example of an in situ sensor suitable for use with the present invention includes the In Situ Removal Monitor offered by Applied Materials, Inc. of Santa Clara, Calif. Similarly, in situ sensor 210 may include devices for measuring capacitance changes, devices for measuring frictional changes, and acoustic mechanisms for measuring wave propagation (as films and layers are removed during polishing), all of which may be used to detect thickness in real time. Furthermore, it should be noted that at least some embodiments of the invention contemplate implementing an in situ sensor capable of measuring both oxide and copper layers. Other examples of wafer property measuring devices contemplated by at least some embodiments of the present invention include integrated CD (critical dimension) measurement tools, and tools capable of performing measurements for dishing, erosion and residues, and/or particle monitoring, etc.

Still, referring to FIG. 2, wafer properties, such as thickness data and/or other information detected by in situ sensor 210, may be forwarded before commencement of, during, or after a manufacturing process, such as a polishing process, in real time, to a control system 215. Hence, if the manufacturing process is a polishing step, control system 215 is implemented to control each of the steps required to obtain a particular wafer profile (as will be discussed in greater detail below). Thus, control system 215 is operatively coupled to, in addition to in situ sensor 210, components of CMP apparatus 20 to monitor and control a number of manufacturing processes.

Control system 215 utilizes data received from in situ sensor 210 to adjust or modify any number of operational parameters to attain one or more target wafer properties. As one example, thickness information received from in situ sensor 210 may indicate that the thickness at a certain region of a wafer (e.g., a central region) is greater than desired. In response, control system 215 may be utilized to increase the polishing time of a particular step. For example, control system 215 may execute a polishing step that polishes at a greater rate at the central region. As will be discussed below, each step may be performed to produce a particular wafer profile. Thus, certain wafer profiles may be attained by modifying an operational parameter (e.g., in the above example, by increasing the time a particular polishing step is performed). In addition to polish time, any number of other parameters may be manipulated to result in a target profile or wafer property, including for example, polishing rate, pressure, slurry composition and flowrate, etc.

A number of carrier head systems 70 (FIG. 1) may be used to perform any number of manufacturing or polishing steps. In this regard, the in situ sensor that at least in some embodiments of the present invention, is envisioned to be a part of each carrier head system is operatively linked to one or more central control systems including, for example, control system 215. In this manner, the feedback from each of the in situ sensors may be monitored individually. As mentioned above, each of these manufacturing steps, in turn, may be used to affect a particular wafer parameter (or profile in the case of wafer thickness). For example, one manufacturing step (e.g., a polishing step) may be utilized to remove greater amounts of a substrate from an outer edge region. Likewise, other manufacturing steps may be used to remove greater amounts of the substrate from a central region.

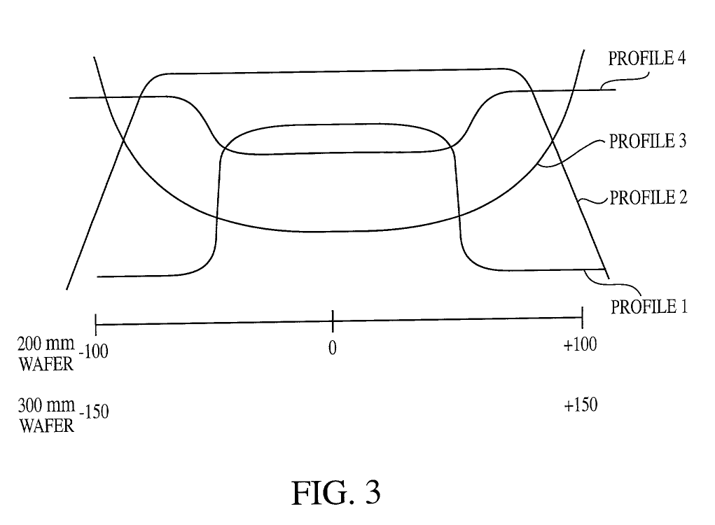

FIG. 3 illustrates at least some examples of a number of polishing profiles attainable by the CMP apparatus 20 to produce a particular wafer thickness through control of a carrier head such as carrier head 100 (FIG. 1). For example, profile 1 results in the removal of greater amounts of substrate from a central region of the wafer. Profile 2 on the other hand removes substrate at a nearly uniform removal rate from the entire wafer. Profile 3 polishes uniformly in the central region and more heavily in outer regions. Profile 4 causes the carrier head systems to polish heavily in the outer edge regions while removing less substrate from a central region. With a polishing process, each carrier head may be capable of processing any or all of these exemplary profiles. Furthermore, other carrier head systems and the like are utilizable in conjunction with the concepts of the present invention.

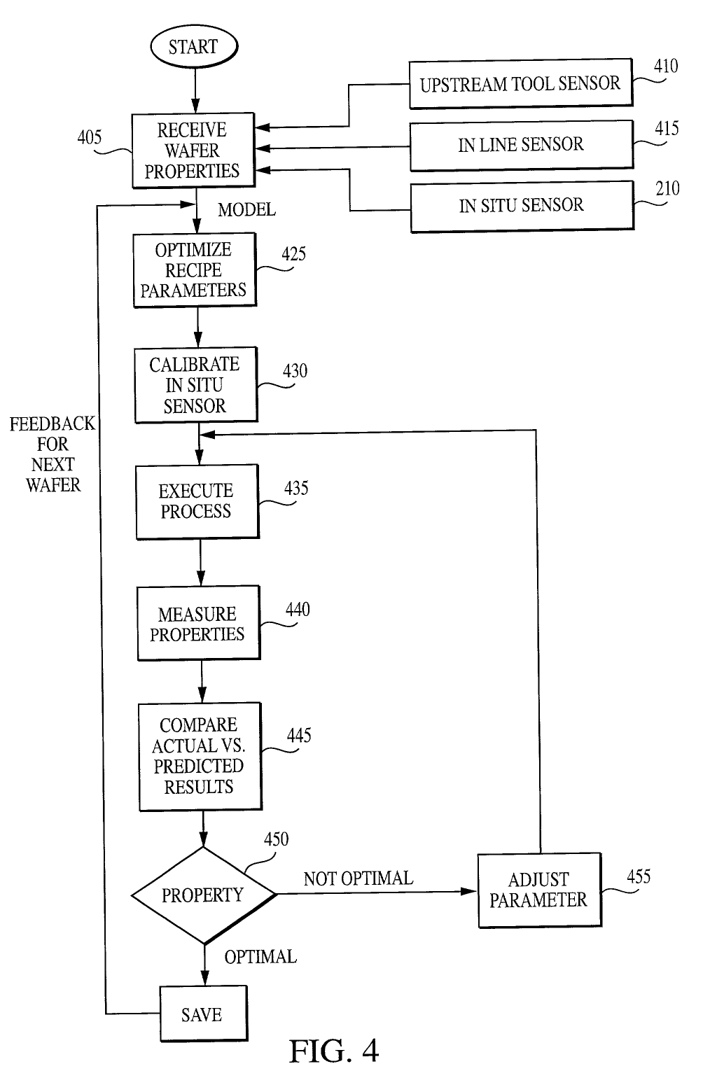

FIG. 4 depicts one example of a process implementable for controlling a manufacturing process contemplated by at least some embodiments of the present invention. Initially, input wafer properties or premesurement information, such as wafer thickness are collected, and fed to an algorithm engine implemented in the control system (STEP 405). As will be discussed below, the input wafer properties are entered into a wafer model, which in turn generates recipe parameters for obtaining an optimal or target wafer property.

These input wafer properties may be received from or collected by any number of sources, including for example, inline sensors 410 or sensors located at a particular tool or platen before, or after a manufacturing step (e.g., sensors located at a polishing tool before a polishing step). One example of such an inline process utilizes tools integrated with metrology techniques (e.g., Nova 2020™ offered by Nova Measuring Instruments, Ltd. of Rehovot, Israel or Nano 9000™ offered by Nanometric of Santa Clara, Calif.).

Input wafer properties may also be received from an upstream measuring tool or feed-forward tool 415 (e.g., a tool positioned upstream from a polishing tool before a polishing step). In this example, the properties may be measured by sensors at another tool at the end of or during a previous manufacturing step and forwarded for use by the process at the instant tool or platen. Examples of such tools include external metrology tools such as the RS-75™ offered by KLA-Tencor of San Jose, Calif.

In other instances, the input wafer properties may be obtained by an in situ sensor positioned to operate in conjunction with the instant tool. In these examples, data may be obtained by sweeping the carrier head, and in situ sensor, across each of the regions of a substrate before executing the process. As discussed above, one example of such an in situ sensor includes the In Situ Removal Monitor offered by Applied Materials, Inc. of Santa Clara, Calif.

At least some embodiments of the present invention contemplate integrating data received from any combination of the above sensors for generating recipe parameters. Similarly, at least some embodiments of the present invention contemplate utilizing data received from inline and upstream tools for calibrating in situ sensors.

After the wafer properties have been forwarded to the control system, a wafer manufacturing model is used to optimize or generate recipe parameters, predicted as being utilizable for producing one or more optimal or target wafer properties (STEP 425). That is, the input wafer properties are used to dynamically generate a recipe for the wafer. Generally speaking, the recipe includes a computer program and/or rules, specifications, operations, and procedures performed with each wafer or substrate to produce a wafer that meets with certain target or optimal characteristics (including for example thickness or uniformity). Typically, the recipe may include multiple steps required to obtain certain outputs. For example, each of the profiles of FIG. 3 may be implemented by a particular step or combination of steps performed by one or a combination of tools. Thus, based on a desired final wafer property and input wafer properties received from the above described sensors, the model may predict a range of recipe parameters predicted as being capable of producing those desired final properties (e.g., thickness or uniformity). As such, based on this data, a recipe is generated to optimize, for example, the within wafer range of the substrate (i.e., the thickness throughout the wafer).

Subsequently, in situ sensor 210 is dynamically calibrated (STEP 430). For example, inline or upstream tool sensor data may be used to reset an in situ sensor to address any changes that may have occurred as a result of normal operation of the manufacturing process.

Once in situ sensor 210 has been calibrated, the manufacturing step is commenced (STEP 435). In the case of a polishing step or process, a carrier head 100 lowers a substrate into contact with a polishing pad 32. Specifically, the substrate 10 is lowered into the polishing pad 32 at a pressure and for a time determined according to the recipe parameters generated by the model of the control system. Once again, although this embodiment is described in the context of a polishing process, other manufacturing processes are also contemplated as being within the concepts of the present invention.

During polishing, in situ sensor 210 continuously measures a wafer property of the substrate (STEP 440). For example, the thickness of the substrate may be measured dynamically in real time by in situ sensor 210. Subsequently, this data (e.g., thickness or other information) is compared against the expected results, as predicted by the control system model (STEP 445). That is, the in situ sensor data is used to compare actual measured results against predictions of the model. Thus, at least some embodiments of the present invention contemplate a model based control or comparison scheme between predictions from the model and actual measured data.

This comparison may then be utilized to modify the manufacturing process. Using the substrate thickness as an example, if the measured or actual thickness is greater or thinner than expected (STEP 450), a parameter of the manufacturing step is modified accordingly. For example, if the measured substrate thickness is greater than predicted, the polishing time may be extended or increased (STEP 455). Likewise, if the measured substrate thickness is less than predicted, the polishing time may be shortened or decreased.

On the other hand, if the actual measured property (e.g., thickness) is optimal or within a target range (STEP 450), the operating parameters, including for example the time at which the target thickness was attained, is saved (STEP 460) and used as feedback for the next wafer. For example, data or information indicating that a shorter polishing time than predicted (e.g., by a model) for obtaining a particular profile may be saved and utilized in conjunction with subsequent wafers. Specifically, a model's subsequent prediction may be modified in accordance with this saved data. Thus, at least some embodiments of the present invention contemplate utilizing information collected from one run in subsequent runs.

In this manner, the process of at least some embodiments the present invention may be used to perform “within wafer” control using in situ sensor data. Further, in situ sensor information may be used for run-to-run control and for distinguishing between platens and platen behavior. For example, as discussed above, data from each in situ sensor may be used dynamically to measure productivity rather than using an averaging of all of the platens. Similarly, input data from upstream tool sensors and inline sensors may be used to calibrate an in situ sensor.

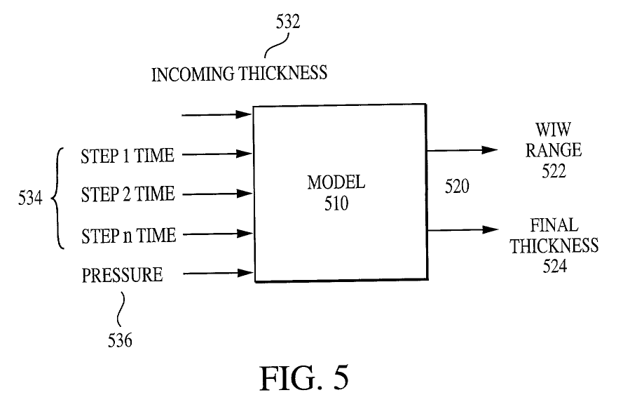

Referring to FIG. 5, one example of a modeling process utilizable for optimizing the recipe parameters of the present invention is described. In particular, input wafer properties measured by, for example an in situ sensor, inline sensor or upstream tool sensor are fed to a control system. For instance, the thickness of the incoming wafer 532, the time required to obtain a particular profile 534, and/or polishing pressure 536 may be entered. From there, the model 510 generates, for example, the recipe parameters 520 predicted as being required to produce a particular output or target property, such as within wafer range 522 and/or a final thickness 524. Thus, using the data collected from the sensors, a wafer model may predict the parameters required to obtain optimal or target results.

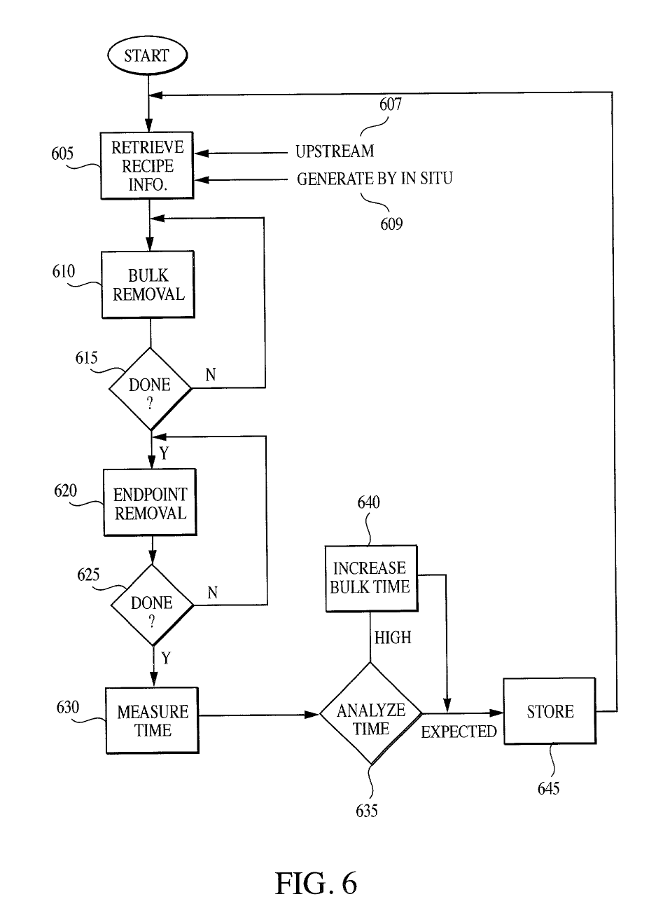

FIG. 6 depicts another embodiment used to illustrate concepts contemplated by the present invention. In this particular embodiment, a polishing tool for a copper process (e.g., a process used to remove copper from a wafer) utilizes a recipe having multiple steps. This recipe utilizes, among other steps, a bulk removal step and an endpoint step. The bulk removal step is used to remove large amounts of copper. The endpoint step, in contrast to the bulk removal step, is a slower polishing step, and is thus used to terminate the polishing process at an endpoint. In this embodiment, the process may be used to address widely varying endpoint times, thereby leading to more consistent overall results and efficiency. Furthermore, although the example depicted in FIG. 6 is shown as being utilized with a copper process, it is to be understood that the techniques described herein may just as easily be utilized with other types of processes, including for example oxide processes.

By monitoring the endpoint time, as measured by in situ sensor 210, and using it as feedback for subsequent runs, the polishing time for each step may be adjusted to take advantage of, for example, the greater polishing rates of the bulk removal step.

The embodiment depicted in FIG. 6 commences with the receipt of wafer recipe data (STEP 605) from an upstream tool or inline sensor (STEP 607) and/or from an in situ sensor (STEP 609). Subsequently, the process enters a bulk removal step (STEP 610), where as discussed above large amounts of substrate may be removed. The bulk removal step continues for a predetermined amount of time (STEP 615), as determined by the wafer recipe.

After the bulk removal step, the process enters an endpoint removal step (STEP 620) which polishes at a rate slower than the bulk removal rate. The endpoint removal step continues until an acceptable endpoint parameter, such as wafer thickness, has been attained (STEP 625). Then, polishing stops.

Once the polishing steps have been completed, the actual time required to reach the wafer endpoint for each step is measured (STEP 630). From there, the measured data is analyzed to identify whether either of the steps may be adjusted to improve efficiency (STEP 635). For example, a relatively long endpoint removal step may suggest that the bulk removal step time may be increased. In this case, it may be possible to significantly reduce, for example, a forty-second endpoint removal time by adding, for example, ten seconds to a bulk removal step.

Accordingly, in this example, if the endpoint removal time is relatively high, the bulk removal time may be increased (STEP 640). In any event, whether the times are adjusted or not, the actual measured times are stored (STEP 645) and used as feedback in subsequently runs. As a result, the data may be used for run-to-run control in subsequent processes.

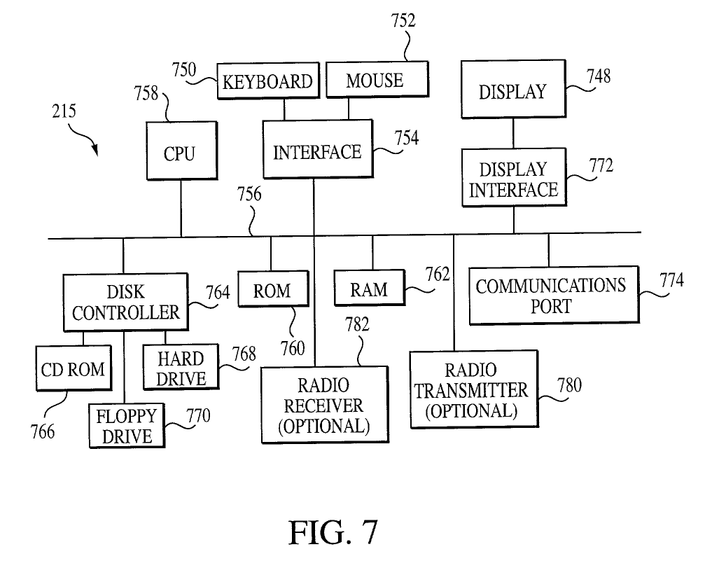

FIG. 7 illustrates a block diagram of one example of the internal hardware of control system 215 of FIG. 2, examples of which include any of a number of different types of computers such as those having Pentium™ based processors as manufactured by Intel Corporation of Santa Clara, Calif. A bus 756 serves as the main information link interconnecting the other components of system 215. CPU 758 is the central processing unit of the system, performing calculations and logic operations required to execute the processes of the instant invention as well as other programs. Read only memory (ROM) 760 and random access memory (RAM) 762 constitute the main memory of the system. Disk controller 764 interfaces one or more disk drives to the system bus 756. These disk drives are, for example, floppy disk drives 770, or CD ROM or DVD (digital video disks) drives 766, or internal or external hard drives 768. CPU 758 can be any number of different types of processors, including those manufactured by Intel Corporation or Motorola of Schaumberg, Ill. The memory/storage devices can be any number of different types of memory devices such as DRAM and SRAM as well as various types of storage devices, including magnetic and optical media. Furthermore, the memory/storage devices can also take the form of a transmission.

A display interface 772 interfaces display 748 and permits information from the bus 756 to be displayed on display 748. Display 748 is also an optional accessory. Communications with external devices such as the other components of the system described above, occur utilizing, for example, communication port 774. For example, port 774 may be interfaced with a bus/network linked to CMP device 20. Optical fibers and/or electrical cables and/or conductors and/or optical communication (e.g., infrared, and the like) and/or wireless communication (e.g., radio frequency (RF), and the like) can be used as the transport medium between the external devices and communication port 774. Peripheral interface 754 interfaces the keyboard 750 and mouse 752, permitting input data to be transmitted to bus 756. In addition to these components, the control system also optionally includes an infrared transmitter 778 and/or infrared receiver 776. Infrared transmitters are optionally utilized when the computer system is used in conjunction with one or more of the processing components/stations that transmits/receives data via infrared signal transmission. Instead of utilizing an infrared transmitter or infrared receiver, the control system may also optionally use a low power radio transmitter 780 and/or a low power radio receiver 782. The low power radio transmitter transmits the signal for reception by components of the production process, and receives signals from the components via the low power radio receiver.

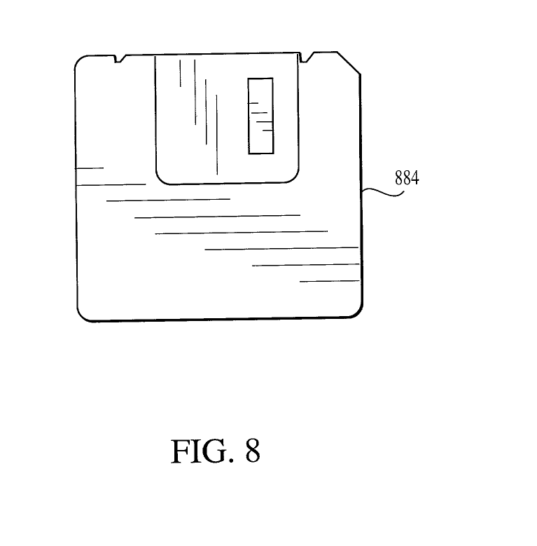

FIG. 8 is an illustration of an exemplary computer readable memory medium 884 utilizable for storing computer readable code or instructions including the model(s), recipe(s), etc). As one example, medium 884 may be used with disk drives illustrated in FIG. 7. Typically, memory media such as floppy disks, or a CD ROM, or a digital video disk will contain, for example, a multi-byte locale for a single byte language and the program information for controlling the above system to enable the computer to perform the functions described herein. Alternatively, ROM 760 and/or RAM 762 can also be used to store the program information that is used to instruct the central processing unit 758 to perform the operations associated with the instant processes. Other examples of suitable computer readable media for storing information include magnetic, electronic, or optical (including holographic) storage, some combination thereof, etc. In addition, at least some embodiments of the present invention contemplate that the computer readable medium can be a transmission.

Embodiments of the present invention contemplate that various portions of software for implementing the various aspects of the present invention as previously described can reside in the memory/storage devices.

In general, it should be emphasized that the various components of embodiments of the present invention can be implemented in hardware, software, or a combination thereof. In such embodiments, the various components and steps would be implemented in hardware and/or software to perform the functions of the present invention. Any presently available or future developed computer software language and/or hardware components can be employed in such embodiments of the present invention. For example, at least some of the functionality mentioned above could be implemented using C or C++ programming languages.

It is also to be appreciated and understood that the specific embodiments of the invention described hereinbefore are merely illustrative of the general principles of the invention. Various modifications may be made by those skilled in the art consistent with the principles set forth hereinbefore.

We claim:

1. A method for controlling a wafer property in a semiconductor processing tool using data collected from an in situ sensor, said method comprising the steps of:
(1) setting recipe parameters relating to said wafer property according to a process model, wherein said model is used to predict wafer outputs;
(2) executing a process on a wafer with the tool according to said recipe parameters;
(3) collecting data relating to said wafer property during execution of said process with said in situ sensor;
(4) adjusting said process by modifying said recipe parameters according to comparisons between said data collected by said in situ sensor relating to said wafer property and results predicted by said model; and
(5) using said data collected by said in situ sensor in a process on a subsequent wafer to be executed by the tool.

2. The method of claim 1, wherein said property comprises wafer thickness.

3. The method of claim 1, wherein said tool comprises a polishing device.

4. The method of claim 1, wherein said tool comprises a plurality of processing resources, each of which includes an in situ sensor, and wherein data from one in situ sensor may be forwarded to another processing resource in real time during execution of said process.

5. The method of claim 1, further comprising the step of collecting data from an inline sensor; and
integrating said data collected from said inline sensor with said data collected from said in situ sensor before processing said subsequent wafer.

6. The method of claim 5, wherein data collected from said inline sensor is utilized to calibrate said in situ sensor.

7. The method of claim 1, further comprising the step of collecting data from a sensor located at an upstream tool; and
integrating said data collected from said upstream tool with said data collected from said in situ sensor before processing said subsequent wafer.

8. The method of claim 7, wherein data collected from said upstream tool is utilized to calibrate said in situ sensor.

9. The method of claim 1, wherein said parameters include a processing time.

10. The method of claim 1, wherein said data collected by said in situ sensor is used for run-to-run control on subsequent wafers processed by said tool.

11. The method of claim 1, wherein said tool comprises a plurality of processing devices, each of which includes an in situ sensor, and wherein data from one in situ sensor may be compared with data from another in situ sensor to in real time to compare results from each device.

12. A method for controlling a wafer property in a semiconductor processing tool using data collected from an in situ sensor, said method comprising the steps of:
(1) collecting data with said in situ sensor relating to said wafer property during a process executed according to wafer recipe parameters;
(2) adjusting said process by modifying said recipe parameters according to comparisons between said data collected by said in situ sensor relating to said wafer property and results predicted by a process model used to predict wafer outputs; and
(3) using said data collected by said in situ sensor in a process on a subsequent wafer to be executed by the tool.

13. The method of claim 12, wherein said step of adjusting comprises increasing or decreasing a processing time.

14. The method of claim 13, wherein said processing time comprises polishing time.

15. The method of claim 12, wherein said tool comprises a plurality of processing resources, each of which includes an in situ sensor, and wherein data from one in situ sensor may be forwarded to another processing resource in real time during execution of said process.

16. The method of claim 12, further comprising the step of collecting data from an inline sensor; and
integrating said data collected from said inline sensor with said data collected from said in situ sensor before processing said subsequent wafer.

17. The method of claim 12, further comprising the step of collecting data from a sensor located at an upstream tool; and
integrating said data collected from said upstream tool with said data collected from said in situ sensor before processing said subsequent wafer.

18. The method of claim 12, wherein said data collected by said in situ sensor is used for run-to-run control on subsequent wafers processed by said tool.

19. A system for controlling a wafer property comprising:
a semiconductor processing tool capable of executing a process for processing a wafer according to recipe parameters relating to a wafer property;
an in situ sensor configured to collect data relating to said wafer property during execution of said process; and
a processor useable for setting said recipe parameters according to a process model for predicting wafer outputs, wherein said processor is utilizable for adjusting said process by modifying said recipe parameters according to comparisons between said data collected by said in situ sensor relating to said wafer property and results predicted by said model, and wherein said processor uses said data collected by said in situ sensor in a process on a subsequent wafer to be executed by the tool.

20. The system of claim 19, wherein said wafer property comprises wafer thickness.

21. The system of claim 19, wherein said tool comprises a polishing device.

22. The system of claim 19, wherein said tool comprises a plurality of processing resources, each of which includes an in situ sensor, and wherein data from one in situ sensor may be forwarded to another processing resource in real time during execution of said process.

23. The system of claim 19, further comprising an inline sensor configured to collect data, wherein said data collected from said inline sensor is integrated with said data collected from said in situ sensor before processing said subsequent wafer.

24. The system of claim 23, wherein data collected from said inline sensor is utilized to calibrate said in situ sensor.

25. The system of claim 19, further comprising a sensor located at an upstream tool configured to collect data, wherein said data collected from said upstream tool is integrated with said data collected from said in situ sensor before processing said subsequent wafer.

26. The system of claim 25, wherein data collected from said upstream tool is utilized to a calibrate said in situ sensor.

27. The system of claim 19, wherein said parameters include a processing time.

28. The system of claim 19, wherein said data collected by said in situ sensor is used for run-to-run control on subsequent wafers processed by said tool.

29. The system of claim 19, wherein said tool comprises a plurality of processing devices, each of which includes an in situ sensor, and wherein data from one in situ sensor may be compared with data from another in situ sensor to in real time to compare results from each device.

30. A system for controlling a wafer property comprising:
an in situ sensor for collecting data relating to said wafer property during a process executed by a semiconductor processing tool according to wafer recipe parameters;
a processor configured to adjust said process by modifying said recipe parameters according to comparisons between said data collected by said in situ sensor relating to said wafer property and results predicted by a process model used to predict wafer outputs; and
wherein said processor is configured to use said data collected by said in situ sensor in a process on a subsequent wafer to be executed by the tool.

31. The system of claim 30, wherein said processor is configured to increase or decrease a a processing time of the tool.

32. The system of claim 31, wherein said processing time comprises polishing time.

33. The system of claim 30, wherein said tool comprises a plurality of processing resources, each of which includes an in situ sensor, and wherein data from one in situ sensor may be forwarded to another processing resource in real time during execution of said process.

34. The system of claim 30, further comprising an inline sensor configured to collect data, and wherein said inline sensor is adapted to integrate said collected data with said data collected from said in situ sensor before processing said subsequent wafer.

35. The system of claim 30, further comprising a sensor located at an upstream tool configured to collect data, and wherein said sensor is adapted to integrate said collected data with said data collected from said in situ sensor before processing said subsequent wafer.

36. The system of claim 30, wherein said data collected by said in situ sensor is used for run-to-run control on subsequent wafers processed by said tool.

37. A system for controlling a wafer property in a semiconductor processing tool using data collected from an in situ sensor, said system comprising:
means for setting recipe parameters relating to said wafer property according to a process model, wherein said model is used to predict wafer outputs;
means for executing a process on a wafer with the tool according to said recipe parameters;
means for collecting data relating to said wafer property during execution of said process with said in situ sensor;
means for adjusting said process by modifying said recipe parameters according to comparisons between said data collected by said in situ sensor relating to said wafer property and results predicted by said model; and
means for using use said data collected by said in situ sensor in a process on a subsequent wafer to be executed by the tool.

38. The system of claim 37, wherein said property comprises wafer thickness.

39. The system of claim 37, wherein said tool comprises a polishing device.

40. The system of claim 37, wherein said tool comprises a plurality of processing resources, each of which includes an in situ sensor, and wherein data from one in situ sensor may be forwarded to another processing resource in real time during execution of said process.

41. The system of claim 37, further comprising means for collecting data from an inline sensor; and
means for integrating said data collected from said inline sensor with said data collected from said in situ sensor before processing said subsequent wafer.

42. The system of claim 41, wherein data collected from said inline sensor is utilized to calibrate said in situ sensor.

43. The system of claim 37, further comprising means for collecting data from a sensor located at an upstream tool; and
means for integrating said data collected from said upstream tool with said data collected from said in situ sensor before processing said subsequent wafer.

44. The system of claim 43, wherein data collected from said upstream tool is utilized to calibrate said in situ sensor.

45. The system of claim 37, wherein said parameters include a processing time.

46. The system of claim 37, wherein said data collected by said in situ sensor is used for run-to-run control on subsequent wafers processed by said tool.

47. The system of claim 37, wherein said tool comprises a plurality of processing devices, each of which includes an in situ sensor, and wherein data from one in situ sensor may be compared with data from another in situ sensor to in real time to compare results from each device.

48. A system for controlling a wafer property in a semiconductor processing tool using data collected from an in situ sensor, said system comprising:
means for collecting data with said in situ sensor relating to said wafer property during a process executed according to wafer recipe parameters;
means for adjusting said process by modifying said recipe parameters according to comparisons between said data collected by said in situ sensor relating to said wafer property and results predicted by a process model used to predict wafer outputs; and
means for using said data collected by said in situ sensor in a process on a subsequent wafer to be executed by the tool.

49. The system of claim 48, wherein said means for adjusting comprises means for increasing or decreasing a processing time.

50. The system of claim 49, wherein said processing time comprises polishing time.

51. The system of claim 48, wherein said tool comprises a plurality of processing resources, each of which includes an in situ sensor, and wherein data from one in situ sensor may be forwarded to another processing resource in real time during execution of said process.

52. The system of claim 48, further comprising means for collecting data from an inline sensor; and
means for integrating said data collected from said inline sensor with said data collected from said in situ sensor before processing said subsequent wafer.

53. The system of claim 48, further comprising means for collecting data from a sensor located at an upstream tool; and
means for integrating said data collected from said upstream tool with said data collected from said in situ sensor before processing said subsequent wafer.

54. The system of claim 48, wherein said data collected by said in situ sensor is used for run-to-run control on subsequent wafers processed by said tool.

55. A computer readable medium for controlling a wafer property in a semiconductor processing tool using data collected from an in situ sensor, said computer readable medium comprising:
computer readable instructions for setting recipe parameters relating to said wafer property according to a process model, wherein said model is used to predict wafer outputs;
computer readable instructions for executing a process on a wafer with the tool according to said recipe parameters;
computer readable instructions for collecting data relating to said wafer property during execution of said process with said in situ sensor;
computer readable instructions for adjusting said process by modifying said recipe parameters according to comparisons between said data collected by said in situ sensor relating to said wafer property and results predicted by said model; and
computer readable instructions for using said data collected by said in situ sensor in a process on a subsequent wafer to be executed by the tool.

56. The computer readable medium of claim 55, wherein said property comprises wafer thickness.

57. The computer readable medium of claim 55, wherein said tool comprises a polishing device.

58. The computer readable medium of claim 55, wherein said tool comprises a plurality of processing resources, each of which includes an in situ sensor, and wherein data from one in situ sensor may be forwarded to another processing resource in real time during execution of said process.

59. The computer readable medium of claim 55, further comprising computer readable instructions for collecting data from an inline sensor; and
computer readable instructions for integrating said data collected from said inline sensor with said data collected from said in situ sensor before processing said subsequent wafer.

60. The computer readable medium of claim 59, wherein data collected from said inline sensor is utilized to calibrate said in situ sensor.

61. The computer readable medium of claim 55, further comprising computer readable instructions for collecting data from a sensor located at an upstream tool; and
computer readable instructions for integrating said data collected from said upstream tool with said data collected from said in situ sensor before processing said subsequent wafer.

62. The computer readable medium of claim 61, wherein data collected from said upstream tool is utilized to calibrate said in situ sensor.

63. The computer readable medium of claim 55, wherein said parameters include a processing time.

64. The computer readable medium of claim 55, wherein said data collected by said in situ sensor is used for run-to-run control on subsequent wafers processed by said tool.

65. The computer readable medium of claim 55, wherein said tool comprises a plurality of processing devices, each of which includes an in situ sensor, and wherein data from one in situ sensor may be compared with data from another in situ sensor to in real time to compare results from each device.

66. A computer readable medium for controlling a wafer property in a semiconductor processing tool using data collected from an in situ sensor, said computer readable medium comprising:
computer readable instructions for collecting data with said in situ sensor relating to said wafer property during a process executed according to wafer recipe parameters;
computer readable instructions for adjusting said process by modifying said recipe parameters according to comparisons between said data collected by said in situ sensor relating to said wafer property and results predicted by a process model used to predict wafer outputs; and
computer readable instructions for using said data collected by said in situ sensor in a process on a subsequent wafer to be executed by the tool.

67. The computer readable medium of claim 66, wherein said computer readable instructions for adjusting comprises computer readable instructions for increasing or decreasing a processing time.

68. The computer readable medium of claim 67, wherein said processing time comprises polishing time.

69. The computer readable medium of claim 66, wherein said tool comprises a plurality of processing resources, each of which includes an in situ sensor, and wherein data from one in situ sensor may be forwarded to another processing resource in real time during execution of said process.

70. The computer readable medium of claim 66, further comprising computer readable instructions for collecting data from an inline sensor; and
computer readable instructions for integrating said data collected from said inline sensor with said data collected from said in situ sensor before processing said subsequent wafer.

71. The computer readable medium of claim 66, further comprising computer readable instructions for collecting data from a sensor located at an upstream tool; and
computer readable instructions for integrating said data collected from said upstream tool with said data collected from said in situ sensor before processing said subsequent wafer.

72. The computer readable medium of claim 66, wherein said data collected by said in situ sensor is used for run-to-run control on subsequent wafers processed by said tool.
